(19) United States
(12) Patent Application Publication
(10) Pub. No.: US 2025/0028889 A1
(43) Pub. Date: Jan. 23, 2025

(54) LOCATION-BASED NOC INTERFACE WITH SUBTOPOLOGIES

(71) Applicant: Signature IP Corporation, Milpitas, CA (US)

(72) Inventors: Kishore Mishra, Santa Clara, CA (US); Michael Loe Fernandez, Quezon City (PH); Ralfael Himor, Manila City (PH); Parag Bhatt, San Jose, CA (US)

(73) Assignee: Signature IP Corporation, Milpitas, CA (US)

(21) Appl. No.: 18/777,679

(22) Filed: Jul. 19, 2024

Related U.S. Application Data
(60) Provisional application No. 63/663,205, filed on Jun. 24, 2024.
(60) Provisional application No. 63/643,941, filed on May 8, 2024.
(60) Provisional application No. 63/551,091, filed on Feb. 8, 2024.
(60) Provisional application No. 63/617,823, filed on Jan. 5, 2024.
(60) Provisional application No. 63/615,862, filed on Dec. 29, 2023.
(60) Provisional application No. 63/601,497, filed on Nov. 21, 2023.
(60) Provisional application No. 63/542,800, filed on Oct. 6, 2023.
(60) Provisional application No. 63/527,832, filed on Jul. 20, 2023.

(51) Int. Cl. G06F 30/3315

(52) U.S. Cl. CPC G06F 30/3315

(57) ABSTRACT

Disclosed embodiments provide techniques for a networking with a network-on-chip (NoC) interface with subtopologies. A system-on-chip (SoC) is accessed. The SoC includes a plurality of logic blocks. A NoC topology is created. The NoC topology includes one or more subtopologies. The one or more subtopologies are based on a physical location of the plurality of logic blocks. Each subtopology includes at least one router. A location of the one or more subtopologies is optimized. The one or more subtopologies are coupled based on one or more communications protocols. A protocol running on the plurality of logic blocks is translated to the one or more communications protocols. Data is sent from a sending subtopology within the one or more subtopologies to a receiving subtopology within the one or more subtopologies.

### RELATED APPLICATIONS

This application claims the benefit of U.S. provisional patent applications “Location-Based NoC Interface with Subtopologies” Ser. No. 63/527,832, filed Jul. 20, 2023, “Flexible Test Instruction Set Architecture” Ser. No. 63/542,800, filed Oct. 6, 2023, “Functional Safety BIST With System Vitals” Ser. No. 63/601,497, filed Nov. 21, 2023, “Trace-Based Testing With Software Access Points” Ser. No. 63/615,862, filed Dec. 29, 2023, “Round Robin Bus Arbitration With Control Vectors and Increment And Decrement Functions”, Ser. No. 63/617,823, filed Jan. 5, 2024, “Weighted Round Robin Bus Arbitration With Control Vectors And Increment And Decrement Functions” Ser. No. 63/551,091, filed Feb. 8, 2024, “Coupling Network-On-Chip Subtopologies With Derivative Clocks” Ser. No. 63/643,941, filed May 8, 2024, and “Cloud-Native Network-On-Chip Validation With Subtopologies” Ser. No. 63/663,205, filed Jun. 24, 2024.

Each of the foregoing applications is hereby incorporated by reference in its entirety.

### FIELD OF ART

This application relates generally to chip floor planning and more particularly to a location-based NoC interface with subtopologies.

### BACKGROUND

Space planning and design are important skills in many artistic and business endeavors. Architects, builders, and landscapers work at placing elements so that spaces function well and are aesthetically pleasing. City planners and zoning boards study traffic patterns, housing requirements, office locations, access to shopping, street lighting, and many other factors as they lay out streets to accommodate current and future needs. Tailors and sewists place patterns on cloth to not only maximize the number of pieces that can be cut out, but also to make sure that the pieces will fit together in a cohesive manner. The processes that go into making the textiles used by clothing manufacturers are themselves marvels of space planning, receiving raw materials such as cotton and wool at one end, spinning them into yarns, dying them, manipulating thread thicknesses, and weaving yarns into cloth within single locations. Home and office decorators consider room functions, traffic flow, scale, proportions, colors, lighting, locations of control panels, and so on in an effort to make work and play spaces enjoyable as well as efficient. Manufacturing processes from cupcakes to automobiles, shipbuilding to wallpaper, require floor layouts that can accommodate machinery, worker safety, maintenance, environmental requirements, down time, storage, and transportation of raw materials as well as finished goods.

Space design can often come down to figuring out how best to add another 5, 10, or 100 workers, tools, or both into the same physical space. Many companies that are successful at first can lose their ability to compete if they are not able to update their spaces and keep up with newer factories with more efficient layouts. Companies with workers on multiple floors of an office building must often plan in three dimensions, considering work efforts to arrange each floor so that communication within the floor and between floors is made as efficient and effective as possible. With the growth of remote workers, office design has had to adapt to greater network and communication demands, finding better ways to connect users from multiple locations across floors, buildings, cities, or continents. Shared spaces are created or re-engineered to allow for both formal and informal collaboration.

Similar considerations are often a part of the electronics industry. In applications that require complex integrated circuits (ICs), circuit boards, or multiple circuit boards, communication can be a critical factor. The complexities and challenges in circuit boards are multiplied even further in advanced chip design. With millions or billions of transistors in a single chip, space planning reaches a pinnacle of complexity. Whether the demand is as simple as furniture in a dorm room or as complicated as the newest computer chip, the need for efficient and effective space planning will continue to challenge our intellect and imagination.

### SUMMARY

As microprocessors have been tasked to handle larger and more complicated workloads, they have grown in size and complexity. Today's microprocessors usually include a number of cores, or processing units, each capable of executing instructions, accessing memory, etc. Further, these multicore processors can form the building blocks for a system-on-chip (SoC), which can include multiple computer subsystems such as memory controllers, I/O controllers such as Peripheral Component Interconnect Express (PCI-E), security logic, and so on. These subsystems within the SoC must communicate with other subsystems in order to accomplish a compute task. For example, a multi-processor core can communicate with a memory controller to access memory that is not on-chip. Because of the size of these SoCs, communication paths can be long, introducing unacceptable RC delays. Further, the amount of complex and dense logic can limit point-to-point wiring channels over some areas. Thus, direct connections between logic blocks (both within and outside of subsystems) can be performance limiting. Network-on-chip (NoC) topologies have been helpful in reducing RC delays by sending information between logic blocks in various subsystems via a packetized interface. A NoC typically includes a set of nodes. Each node can include one or more routers near the logic blocks that must communicate with each other. Logic blocks must simply connect to the nearest NoC node to send data to another logic block which may be far away. However, as SoCs continue to grow in size, a single NoC topology can limit performance as it is nearly impossible to eliminate long wire delays. These delays may not meet timing requirements and are not performance scalable with long-standing industry trends towards smaller feature sizes, thus risking future performance limitations.

Disclosed embodiments provide techniques for a location-based network-on-chip (NoC) interface with subtopologies. A system-on-chip (SoC) is accessed. The SoC includes a plurality of logic blocks. A NoC topology is created. The NoC topology includes one or more subtopologies. The one or more subtopologies are based on a physical location of the plurality of logic blocks. Each subtopology includes at least one router. A location of the one or more subtopologies is optimized. The one or more subtopologies are coupled based on one or more communications protocols. A protocol running on the plurality of logic blocks is translated to the one or more communications protocols. Data is sent from a sending subtopology within the one or more subtopologies to a receiving subtopology within the one or more subtopologies.

SoC performance is improved by a location-based NoC interface with subtopologies. Disclosed embodiments provide a computer-implemented method for chip floor planning comprising: accessing a system-on-chip (SoC), wherein the SoC includes a plurality of logic blocks; creating a network-on-chip (NoC) topology, wherein the topology includes one or more subtopologies, wherein the one or more subtopologies are based on a physical location of the plurality of logic blocks, and wherein each subtopology in the one or more subtopologies includes at least one router; optimizing a location of the one or more subtopologies; placing the one or more subtopologies within the SoC, wherein the placing is based on the optimizing; and coupling the one or more subtopologies that were placed, wherein the coupling is based on one or more communications protocols. Embodiments include sending data from a sending subtopology within the one or more subtopologies to a receiving subtopology within the one or more subtopologies. Other embodiments include inserting a first interfacing block between the sending subtopology and the receiving subtopology. Further embodiments include translating, from a protocol running on the plurality of logic blocks, to the one or more communications protocols.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a location-based NoC interface with subtopologies.

FIG. 2 is a flow diagram for inserting interface blocks.

FIG. 3 is an example NoC node.

FIG. 4 is an example of a NoC subtopology within an SoC subsystem.

FIG. 5 is a sample floor plan for subtopologies within an SoC.

FIG. 6 is a sample floor plan for subtopologies with interfacing blocks.

FIG. 7 is a system diagram for a location-based NoC interface with subtopologies.

### DETAILED DESCRIPTION

Advances in technology such as artificial intelligence, genomic sequencing, autonomous vehicle operation, virtual reality, etc. have caused an ever increasing demand for compute power. System-on-chip (SoC) architectures have proven useful in addressing compute resources needed for such tasks. Today's SoC designs can include multiple subsystems such as processor cores, multiprocessor cores, I/O controllers, security protocols, and so on. Because they can include many such logical subsystems, the trend toward SoC chips has led to a significant increase of chip transistor counts. As transistor counts increase, significant challenges can arise in wiring logic blocks within the SoC with limited wiring channels in densely packed floor plans. For example, traditional point-to-point wiring can prove infeasible as many wide buses must be coupled to multiple logic blocks. These buses must often communicate over long, critical timing paths. To mitigate these issues, additional interconnection techniques have been adopted. One such technique is a network-on-chip (NoC) approach. The NoC applies networking technology at the chip level, connecting high level logic blocks together through packetized communications. This approach can increase performance over traditional communication buses and enable a user to more easily swap out or modify IP blocks within the SoC. NoCs can be implemented in a number of network topologies, including direct or indirect topologies. Direct topologies can include one or more routers associated with each SoC subsystem and direct messages in and out of the subsystem. A message between two subsystems can travel through one or more routers that are associated with various subsystems. Indirect topologies can include routers that are not coupled to subsystems but exist only to carry messages to other routers. A NoC can include both direct and indirect topology elements. A NoC can include a specific topology such as a ring, an n-dimensional mesh, a torus, a k-ary tree, a cube, and so on.

As SoC chip counts continue to rise, new limitations of NoC technology have become evident. Typically, a NoC topology features a large main NoC that is placed with the SoC. Optimizations for placement, timing, etc. can be performed within the NoC, however, these are made separately from logic optimizations made within subsystems of the SoC. The result can be difficult to solve wire congestion and long RC delays which do not scale as feature sizes are reduced in subsequent manufacturing technologies. Disclosed embodiments enable a location-based NoC with subtopologies. The subtopologies can be used to solve these complex floor planning, timing, and performance issues by allowing optimizations to occur within the logical blocks and associated NoC subtopologies concurrently.

Techniques for chip floor planning using networking on a system-on-chip (SoC) are disclosed. The networking is enabled by accessing a system-on-chip (SoC). The SoC can include a plurality of subsystems. The subsystems can include a processor, caches, peripheral communications logic, security logic, and so on. The subsystems can comprise one or more logic blocks on the SoC. A network-on-chip (NoC) topology is created. The NoC topology includes one or more subtopologies. The one or more subtopologies are based on a physical location of the plurality of logic blocks. Each subtopology in the one or more subtopologies includes at least one router. A location of the one or more subtopologies is optimized. One or more logic blocks within the plurality of logic blocks can be selected to be included in each of the one or more subtopologies. The one or more logic blocks can be selected from different SoC subsystems. The selection can be based on timing within the one or more logic blocks. The one or more subtopologies are placed within the SoC. The placing is based on the optimizing. The one or more subtopologies that were placed are coupled. The coupling can be based on one or more communications protocols. A protocol running on the plurality of logic blocks can be translated to the one or more communications protocols. A first interfacing block can be inserted between the sending subtopology and the receiving subtopology. A second interfacing block can be added between the first interfacing block and the receiving subtopology.

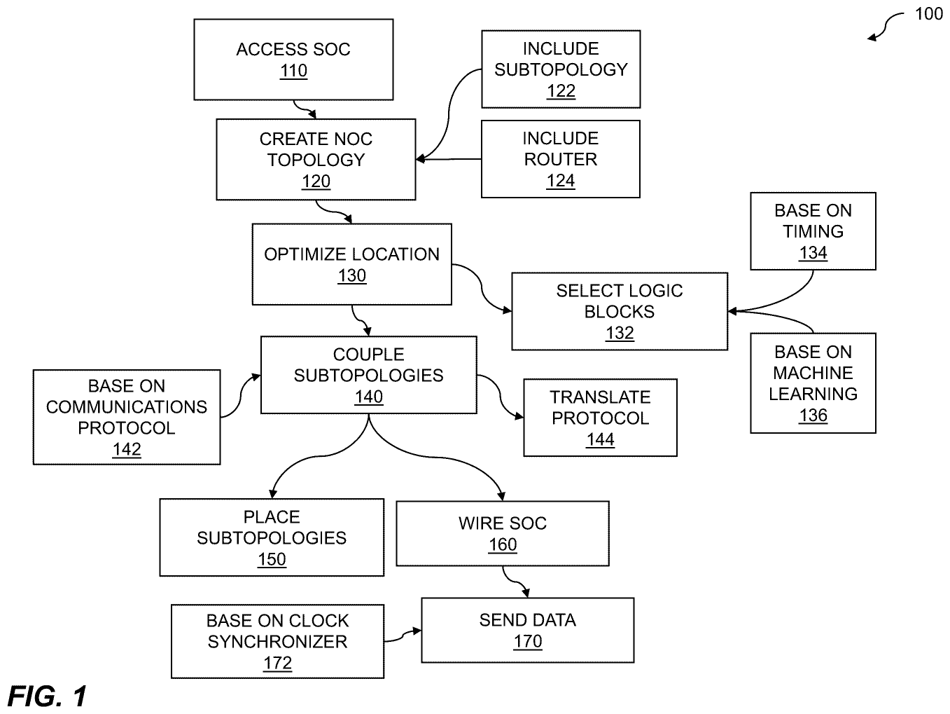

FIG. 1 is a flow diagram 100 for a location-based NoC interface with subtopologies. A system-on-chip (SoC) is accessed. Advanced SoC chip floor planning is enabled by a NoC interface with subtopologies. A system-on-chip (SoC), which includes a plurality of logic blocks, is accessed. The logic blocks can comprise one or more subsystems on the SoC. The logic blocks can implement a coherent or non-coherent communications protocol. A NoC topology, that includes one or more subtopologies, is created. The one or more subtopologies are based on a physical location of the plurality of logic blocks. The communications protocol implemented by the logic blocks can be translated to a communications protocol running on the subtopologies. Each subtopology includes at least one router. A location of the one or more subtopologies is optimized, placed within the SoC, and coupled based on one or more communications protocols. Data is sent from a sending subtopology to a receiving subtopology. To further enable communication between subtopologies, interfacing blocks can be inserted between a sending subtopology and a receiving subtopology. The interfacing block can synchronize data that was sent by the sending subtopology. A clock signal from the sending topology can be sent to the receiving subtopology via the interfacing blocks.

The flow 100 includes accessing a system-on-chip (SoC) 110. In embodiments, the SoC includes one or more logic blocks. The logic blocks can comprise one or more subsystems on the SoC. The subsystems can include one or more processors, memory, input/out devices, external interfaces, graphics processor units (GPUs), modems, security logic, and the like. The SoC can be a multi-core SoC (MCSoC). The logic blocks on the SoC can be integrated on a single silicon chip and can be paired with physically separate memory such as Low-Power Double Data Rate (LDDR), Embedded Universal Flash Storage (cUFS), Embedded Multi-Media Card (eMMC) chips, and so on. These chips can be placed in a package-on-package configuration to ensure proximity to the SoC. The logic blocks on the SoC can communicate via different protocols. These protocols can be a mix of coherent communications protocols (such as AMBA 5 CHI) and non-coherent communications protocols (such as AMBA AXI). In a usage example, an SoC with multiple processors that share a higher level cache such as an L2 cache can run a coherent protocol, such as AMBA CHI, to ensure that each processor in the SoC does not consume stale data.

The flow 100 includes creating a network-on-chip (NoC) topology 120. Methods of communications can be enabled between and among logic blocks, subsystems, etc. within the SoC. These methods can include buses, crossbar switches, and so on. However, these mechanisms can limit cycle times and add design complexity. In many cases, a NoC topology can offer improvements via router-based packetized communications within, between, into, out of, etc. subsystems. The NoC topology can include a communications structure such as a ring, an n-dimensional mesh, a torus, a k-ary tree, a cube mesh, or any other structure. In embodiments, the NoC topology includes one or more subtopologies 122. Any of the subtopologies can include elements of indirect or direct topologies. Direct topologies can include one or more routers associated with each SoC subsystem and direct messages in and out of the subsystem. Indirect topologies can include routers that are not connected to subsystems, but exist only to carry messages to other routers. The subtopologies can include logic, physical wiring, one or more subtopology nodes, and so on. Subtopology nodes can comprise a network interface, a router, ingress ports, egress ports, physical links such as wiring, etc. The network interface can packetize and/or depacketize data and translate between different communications protocols utilized by various logic and/or subsystems on the SoC, as described above. The network interface can be included in logic blocks within the SoC subsystems rather than the NoC nodes. In embodiments, each subtopology in the one or more subtopologies includes at least one router 124. The routers can include ingress and egress ports. The routers can direct packetized network traffic to other subtopologies within and/or outside of a subsystem. The ingress and egress ports can couple a logic block within a subtopology to another logic block in the subtopology, another node in the subtopology, a node in a different subtopology, and so on. Packetized network traffic sent between nodes can include data, a logic block ID, coherency data, priority information, or other data. In other embodiments, the one or more subtopologies are based on a physical location of the plurality of logic blocks. Dividing the NoC subtopology into subtopologies enables additional flexibility to meet performance goals. For example, when located in close physical proximity, the logic blocks can be concurrently synthesized, simulated, timed, etc. with the NoC subtopology which services them.

The flow 100 includes optimizing a location 130 of the one or more subtopologies. The physical location of each NoC subtopology can be arranged on the SoC to optimize communications between logic blocks within or between subsystems. For example, the position of a first subtopology within a first subsystem can be moved closer to a second subtopology in a second subsystem to improve timing of communications between the two subsystems. Subtopologies can be positioned within a single subsystem, between two subsystems, and so on. Optimizing subtopology placement can eliminate timing issues due to long packetized signals. The optimizing can be based on a human designer, a place-and-route algorithm, machine learning, machine learning NoC (MLNoC) technology, and so on. The results of the optimizing can be modified by a human designer to further optimize for a variety of design factors such as timing, bandwidth, and so on. The optimization can include synthesizing the subtopology with different parameters such as timing constraints, logic minimization, and so on. The synthesizing can include concurrently synthesizing the subtopology and one or more logic blocks to maximize performance, minimize logic, improve timing, and so on.

In embodiments, the optimizing is based on latency. When optimizing the location of the subtopologies, care can be taken to arrange the subtopologies such that wire delays within critical timing paths are minimized. However, this movement can also exacerbate timing issues in other paths between the same or difference subtopologies. The exact position of the one or more subtopologies can be optimized, taking into consideration the timing constraints of each logic timing path coupled to the subtopologies. In addition, nodes within the subtopology can be located to minimize timing delay in logic blocks that have timing challenges. Additional nodes can be added within the subtopology, as space permits, to help solve timing issues as well. In embodiments, the optimizing is based on machine learning. The machine learning can be based on any type of machine learning model such as a neural network (NN), convolutional neural network (CNN), K-nearest neighbor algorithm (KNN), and so on. The machine learning model can be trained and used to optimize the location for the NoC subtopologies on the SoC to eliminate as many long signal delays as possible. The machine learning can take into account one or more timing estimates of one or more logical paths that include one or more logical blocks, and/or one or more NoC subtopologies. In other embodiments, the optimizing is based on bandwidth. The location of the subtopologies can be arranged such that paths that are known to carry significant data bandwidth can see minimal packet delay when transmitting data between subtopology nodes. This can be accomplished by placing a minimum number of subtopology nodes in the path from a logic block to another logic block in the same or another subsystem. This path can include one or more subtopologies.

In embodiments, the optimizing includes selecting one or more logic blocks 132 with the plurality of logic blocks to be serviced by each of the one or more subtopologies. As described throughout, logic blocks can be assigned a subtopology with the NoC to enable and optimize communication between logic blocks on the SoC. In embodiments, the one or more logic blocks are from different SoC subsystems. Any logic block can be assigned to any subtopology. For example, a logic block within a processor subsystem may be associated with a processor subtopology. As the design progresses, it may become advantageous to include the logic block with a NoC subtopology associated with a security subsystem. Thus, the logic block can be optimized (timed, synthesized, and/or floorplanned, etc.) with the security subsystem, not the processor subtopology. The logic blocks that are assigned to a NoC subtopology can be reassigned at any time. Selecting one or more logic blocks to be serviced by a particular NoC topology can be based on many factors. In embodiments, the selecting is based on timing 134 within the one or more logic blocks. For example, if the timing of signals within the logic block is critical or tight, a close NoC subtopology can be chosen. The location of nodes within the subtopologies can also be optimized. For example, a node within the NoC subtopology can be added, moved, etc. closer to the logic block to reduce RC delays when sending and/or receiving communications over the NoC. In embodiments, the selecting is based on machine learning 136. The machine learning can be based on any type of machine learning model such as a NN, CNN, KNN, and so on. The machine learning model can be trained and used to optimize the selection of various logic blocks to be serviced by a subtopology. The machine learning can take into account timing data associated with paths in and between the logical blocks on the SoC. Other optimizations are possible. For example, the size of any subtopology can be changed. Additionally, nodes can be added to or subtracted from any subtopology to case timing issues. Various logic blocks can be included in a subtopology inside a subsystem or a neighboring subsystem. Logic blocks can be floorplanned without coupling to a NoC subsystem.

The specific structure of the subtopologies can be based on the best fit for the physical structure or location of the logic blocks within the subtopology. The subtopology structure can be based on the shape of the logic block. For example, a more regular structure, such as a mesh, can be the best fit for a logic block that is implemented in a regular shape, such as a rectangle, on the SoC. Conversely, a regular topology may not be the best choice for a logic block laid out in an irregular shape. The size of the subtopology can be based on the size of the logic block. For example, a small logic black may not require its own dedicated subtopology. Instead, it may be small enough to connect to another subtopology while still being able to meet timing and bandwidth requirements. An existing subtopology can be placed such that it overlaps with the small logic block to case timing issues. Additional nodes can be added to the existing subtopology to provide coupling to the small logic block.

The flow 100 includes coupling the one or more subtopologies 140 that were placed. The coupling can include one or more nodes. As described above, a node can comprise a network interface, a router, ingress ports, egress ports, physical wiring, etc. The coupling can include any number of nodes. For example, a first node in a first subtopology can be coupled to a first node in a second subtopology. In addition, a second node in the first subtopology can be coupled to a second node in the second subtopology. Subtopologies within the NoC can vary in data width, clocks, and so on. The coupling can ensure that data can be sent/received between subtopologies. For example, the coupling can include buffers to ensure that data is not lost when a subtopology with a larger data width (e.g., 512 bits) sends data to a subtopology with a smaller data with (e.g., 128 bits). A sending subtopology and a receiving subtopology can implement different clock domains. In this case, the coupling can include a data synchronizer (described below) to cross clock domains without losing data. In embodiments, the coupling is based on one or more communications protocols 142. The communications protocol can include packets. Information can be sent in the form of packets from a sending node to a receiving node within the same subtopology or a different subtopology. The communications protocol can include unidirectional, bidirectional, etc. communications between the sending node and receiver nodes. Thus, the communications protocol can include handshaking between the one or more subtopologies. In embodiments, separate read and write data buses are provided between the nodes. Thus, the read and write data buses can be unidirectional and the communications protocol can provide a unidirectional data transfer between nodes of the subtopology. In embodiments, the one or more communications protocols are coherent, such as AMBA CHI. A coherent system can ensure that caches within subsystems of the SoC share data and that no cache obtains data that is out of date. In other embodiments, the one or more communications protocols are non-coherent, such as AMBA AXI. In a non-coherent protocol, each subsystem must manage caches independently from other subsystems. The flow 100 includes translating, from a protocol running on the plurality of logic blocks, to the one or more communications protocols 144. The translating can include packetizing signals from the logic blocks so that they can be sent over the NoC and depacketizing signals after the signals are sent. The packetizing can be accomplished by a network interface which can be included on one or more nodes within a subtopology. Alternatively, the network interface can be included in logic blocks within the SoC subsystems rather than the NoC nodes.

In embodiments, the coupling can include placing the one or more subtopologies 150 within the SoC. In embodiments, the placing is based on the optimizing. Once logic blocks are assigned to an appropriate NoC subtopology and the location of the subtopologies on the SoC and the nodes within the NoC subtopology are decided, the NoC subtopology can be placed within the SoC floorplan. The placing can include instantiating the subtopology. The placing can occur concurrently with placing logic blocks on an entire subsystem. Once placed, routing can then be finalized. The routing for the logic blocks and the subtopology can occur concurrently allowing for optimization of wiring channels, latency, and bandwidth. The routing can be based on any place-and-route algorithm. The input constraints of the place-and-route algorithm can be adjusted for iterative passes. The results of the algorithm can be modified by a human designer.

The flow 100 includes wiring, using one or more processors, the SoC 160. In embodiments, the wiring includes the one or more subtopologies. The wiring can include a power grid to connect power to the logic blocks and subtopologies. The wiring can include a clock signal. The clock signal can be a global clock signal for the SoC or a local clock signal for one or more logic blocks. The global or local clock signal can be distributed to one or more of the subtopologies. In embodiments, different clock signals can be wired to various logic blocks or subtopologies. SoC input and output signals can be wired to external pins of the SoC package. The wiring can be based on an automated wiring algorithm. In embodiments, verification checks can be run to ensure that all connectivity is what was intended.

The flow 100 includes sending data 170 from a sending subtopology within the one or more subtopologies to a receiving subtopology within the one or more subtopologies. As mentioned previously, data from any logic block can be translated to a communications protocol, such as a packetized protocol running on a NoC subtopology. The translating can be accomplished by a node within the one or more subtopologies. The packets can be sent from a sending node within the sending subtopology to a receiving node in the receiving subtopology using the communications protocol. The packets can comprise a number of flits, or flow control units. The first flit can comprise header information which can define a routing path to the receiving node. The routing path can include a plurality of intermediate nodes. The intermediate nodes can be in different subtopologies. The intermediate nodes can decode the header to determine the continued routing path to the receiving subtopology. The header can indicate the final receiving node. One or more routers in the nodes used to send the data can perform a routing calculation to determine the best path to the receiving node.

The sending subtopology and the receiving subtopology can include synchronous clocks. In this case, data can be sent from the first subtopology to the receiving subtopology using a synchronous First-In-First-Out (FIFO) buffer. The sending subtopology and the receiving subtopology can include different clock domains. In embodiments, a first clock within the sending subtopology and a second clock within the receiving subtopology are asynchronous. Data can be synchronized between the two subtopologies. In further embodiments, the sending is based on a clock synchronizer 172. A clock synchronizer can ensure that data is not lost when transmitting between two different clock domains. The clock synchronizer can comprise a two-flip-flop synchronizer, a toggle synchronizer, a pulse synchronizer, and so on. In embodiments, the clock synchronizer is based on an asynchronous FIFO. The asynchronous FIFO can use the first clock from the sending topology as a write clock while the clock from the receiving subtopology can be used for the read clock. In further embodiments, the sending includes credit-based backpressure. Credit-based backpressure can include notifying, by the receiving topology, that buffer space is available (giving credit to the sending subtopology) to receive data from the sending subtopology. The sending topology can then safely send the data. If no buffer space is available in the receiving subtopology, then credit can be removed resulting in pausing, by the sending subtopology, the sending of data until the receiving subtopology can free up additional buffer space to receive additional data.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

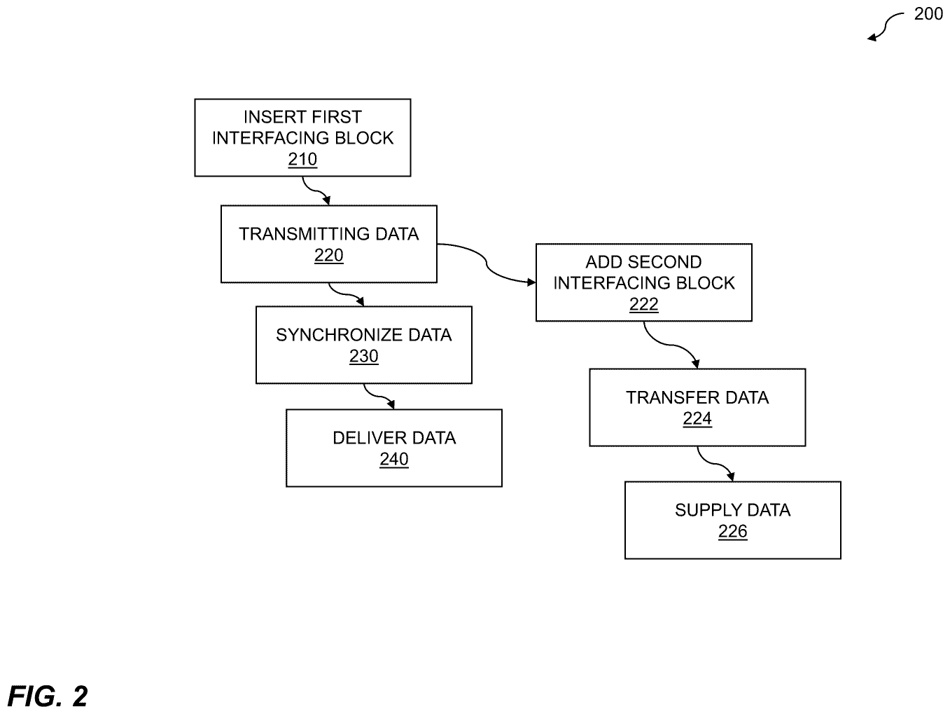

FIG. 2 is a flow diagram for inserting interface blocks. The distance between two subtopologies can be longer than is allowed to meet timing constraints. When this occurs, an interfacing block can be inserted into the overall NoC. The interfacing block can be placed inside or outside of any subtopology. The interfacing block can synchronize data when a sending subtopology is based on a different clock than a receiving subtopology. Additional interfacing blocks can be added in series or in parallel. This can further reduce long wire (RC) delays and/or increase bandwidth when sending data between subtopologies. Since a sending and receiving subtopology can be based on different data widths, the interfacing blocks can include buffers to ensure that data is not lost when a subtopology with a greater data width is sending data to a subtopology with a narrower width.

As previously described, data can be sent from a sending subtopology to a receiving subtopology within the NoC. The flow 200 includes inserting a first interfacing block 210 between the sending subtopology and the receiving subtopology. A system reference clock can be distributed to the SoC through the interfacing block to the subtopologies. The interfacing blocks can synchronize data between subtopologies. In a usage example, floor planning restraints may require a long wire path from the sending subtopology to the receiving subtopology. In this case, timing requirements may require a pipeline state to be added. The interfacing block can comprise the pipeline stage necessary to meet timing requirements. Interfacing blocks can be used when a sending subtopology is sending data to a receiving subtopology with a different width data bus. For example, if the sending subtopology with a 64-bit data bus sends data to a receiving subtopology with a 32-bit data bus, buffers within an interfacing block can store up to 32 bits of data per clock cycle in order to prevent data loss. The data buses can implement backpressure based on credit. Credit-based backpressure can include sending, by the sending subtopology, data only when given “credit” by the receiving subtopology. Credit can be given when there is available buffer space in the receiving subtopology. Credit can be removed when the buffers are full or about to be full, pausing the sending subtopology from sending additional data until credit is restored.

The flow 200 includes transmitting the data 220 from the sending subtopology to the first interfacing block. As described previously, a logic block can be coupled to a network interface that can couple the logic block to the NoC. The network interface can packetize and/or depacketize data and translate between different communications protocols utilized by various logic and/or subsystems on the SoC. The network interface can be included in logic blocks within the SoC subsystems rather than the NoC nodes. The data can be directed by a router, which can be included in a node along with the network interface. The data can be sent to one or more nodes within the NoC subtopology or a node within another NoC subtopology. The data in one node can be placed on a physical link that carries the data to the next node. The physical link can be a wire. A sending subtopology can also send a clock signal that can be used to synchronize data between nodes or subtopologies.

The flow 200 includes synchronizing the data 230, wherein the synchronizing is based on the first interfacing block. A clock within the sending subtopology can be sent, via the interfacing block, to the receiving subtopology within the communications protocol. A node within the receiving subtopology can receive the clock. When clocks between the sending and receiving subtopologies are synchronous, a synchronous FIFO can be used by the interfacing block to synchronize data. Interfacing blocks can enable the transfer of data between subtopologies when the clock frequency is different between the subtopologies. When clocks between the sending and receiving subtopologies are synchronous, an asynchronous FIFO can be used by the interfacing block to synchronize data. In further embodiments, the interfacing blocks are inserted within a subtopology. In still other embodiments, the interfacing blocks are inserted in the SoC outside any subtopology. The flow 200 includes delivering, by the first interfacing block, to the receiving subtopology, the data 240. The delivering can include a clock from the interfacing block to synchronize the data, as described above, at the receiving subtopology. Buffers within the interfacing blocks can enable sending data between subtopologies with different width data buses. For example, if the sending subtopology with a 64-bit data bus sends data to a receiving subtopology with a 32-bit data bus, buffers within an interfacing block can store up to 32 bits of data per clock cycle in order to prevent data loss. The data can then be delivered, in 32-bit increments, to the receiving block.

In embodiments, the inserting includes adding a second interfacing block 222 between the first interfacing block and the receiving subtopology. Any number of additional interfacing blocks can be added between subtopologies. The additional interfacing blocks can comprise pipeline stages. The additional interfacing blocks can be added within a sending subtopology, a receiving subtopology, or outside of any subtopology. The interfacing blocks can be synthesized, floorplanned, timed, etc. with other logic elements of the SoC. Embodiments include transferring the data 224 from the first interfacing block to the second interfacing block. The transferring can include handshaking between the first interfacing block and the second interfacing block. Separate read and write data buses can be provided between the interfacing blocks. The read and write data buses can be unidirectional. The first interfacing blocks can also send a clock signal that can be used to synchronize data between the interfacing blocks. A clock can also be forwarded between interfacing blocks to synchronize data using the methods described above. Other embodiments include supplying, by the second interfacing block, to the receiving subtopology, the data 226. Data can be sent from the second interfacing block to a node within the receiving topology. A clock signal can also be forwarded from the second interfacing block to synchronize data using the aforementioned methods.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

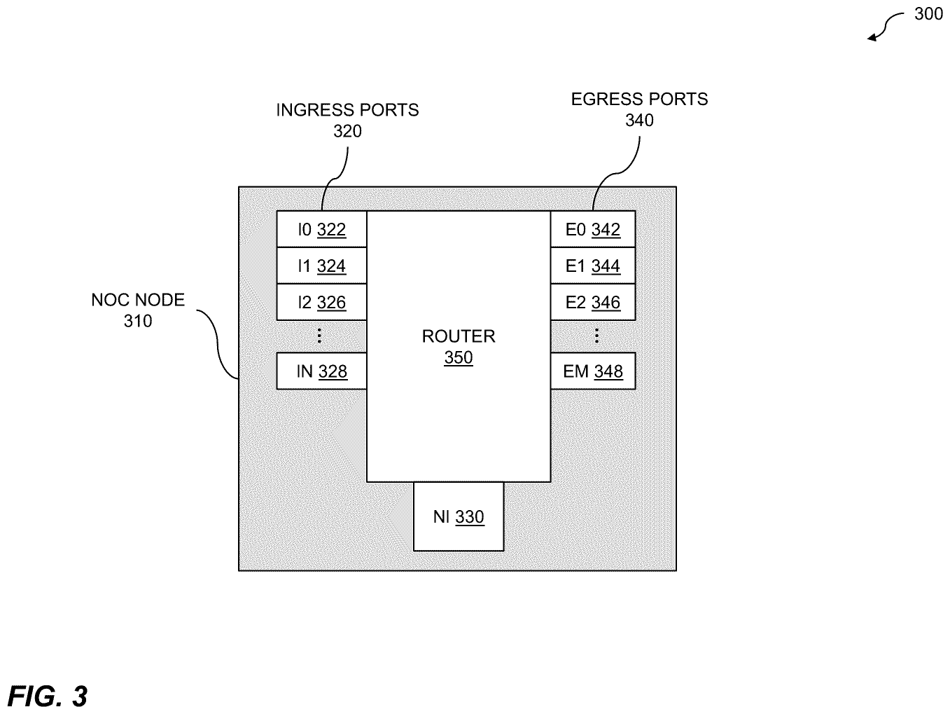

FIG. 3 is an example NoC node. A subtopology can include any number of NoC nodes. The NoC nodes can comprise a router, ingress ports, egress ports, one or more physical links, etc. The NoC node can include a network interface. The network interface can include a controller, packetizer, depacketizer, and so on. The network interface can couple logic signals with the NoC protocol via the NoC node. The nodes within a subtopology can be placed as needed to optimize timing of paths that must communicate with other subsystems on the SoC. In the example 300, a NoC node 310 is shown. The NoC node can receive packet information from any number of upstream sending nodes through one or more ingress ports 320. The packet information can comprise a number of flits, or flow control units. In embodiments, the first flit comprises header information which can define the routing path to the receiving node. The routing path can include any number of subtopologies, nodes, or interfacing blocks. The receiving node can decode the header to determine the routing path. The header can indicate the final receiving node. In this case, one or more routers in the subtopology can perform a routing calculation to determine the best path to the receiving node.

In the example 300, ingress ports I0 322, I1 324, and I2 326 are shown. The NoC node can include any number N of ingress ports indicated by IN 328. Each ingress port can be coupled to a sending node in a common subtopology or a different subtopology. Any number of sending nodes can be coupled to the NoC node by the ingress ports. The ingress ports can function as links to one or more sending nodes. The number of sending nodes can be defined by one or more subtopologies which can include various structures. In embodiments, the one or more subtopologies form an n-dimensional mesh topology. In other embodiments, the one or more subtopologies form a torus topology. Other topologies, such as a ring, a k-ary tree, a cube mesh, and so on, are possible.

The NoC node can include a network interface 330. The network interface can receive and/or send data from/to logic blocks within one or more SoC subsystems via the network interface 330. The network interface can include a controller, packetizer, depacketizer, and so on. Thus, data within a logic block can be sent to the NoC node to be packetized, via a sending network interface, before sending it on to another node in the same or a different subtopology. Likewise, packetized data can be depacketized and sent to one or more logic blocks coupled to the network interface. The network interface can be included in one or more logic blocks instead of within the NoC node shown in the example 300. When included in the logic blocks rather than the NoC node, a plurality of network interfaces can send packetized data directly to an ingress port of the NoC node.

The NoC node can send packet information to any number of downstream receiving nodes through egress ports 340. In the example 300, egress ports E0 342, E1 344, and E2 346 are shown. The node can include any number M of egress ports indicated by EM 348. Each egress port can be coupled to another receiving node in the same subtopology or in a different subtopology. Any number of downstream receiving nodes in any number of subtopologies can be coupled to the NoC node by the egress ports. The NoC node can include a router 350. The router can couple any number of N ingress ports to any number of M egress ports. In embodiments, the router can include buffers, a switch, an arbiter, or other components. The buffers can be organized in FIFO implementation which can be configured to store one or more flits, or flow control units, within a packet sent from a sending node to the NoC node via one or more ingress ports. The router can perform a routing calculation to determine an optimal path of a packet from a sending node to a destination node. The routing calculation can be based on a header flit of a packet sent by a sending subtopology. The destination node can be within the same NoC subtopology as the sending node, within a different NoC subtopology, or outside any subtopology. The routing calculation can include factors such as bandwidth, network delay, latency, number of hops between nodes, network congestion, Quality of Service (QOS) and so on. The router can include a switch which can connect any of N ingress ports to any of M egress ports shown. The switching of ingress ports to egress ports can be based on the routing calculation. In embodiments, the switch can include a crossbar switch. The router can include an arbiter. The arbiter can determine which ingress port is allowed priority access to the switch at any point in time. In embodiments, the arbiter can implement round robin, fixed priority, or another arbitration protocol.

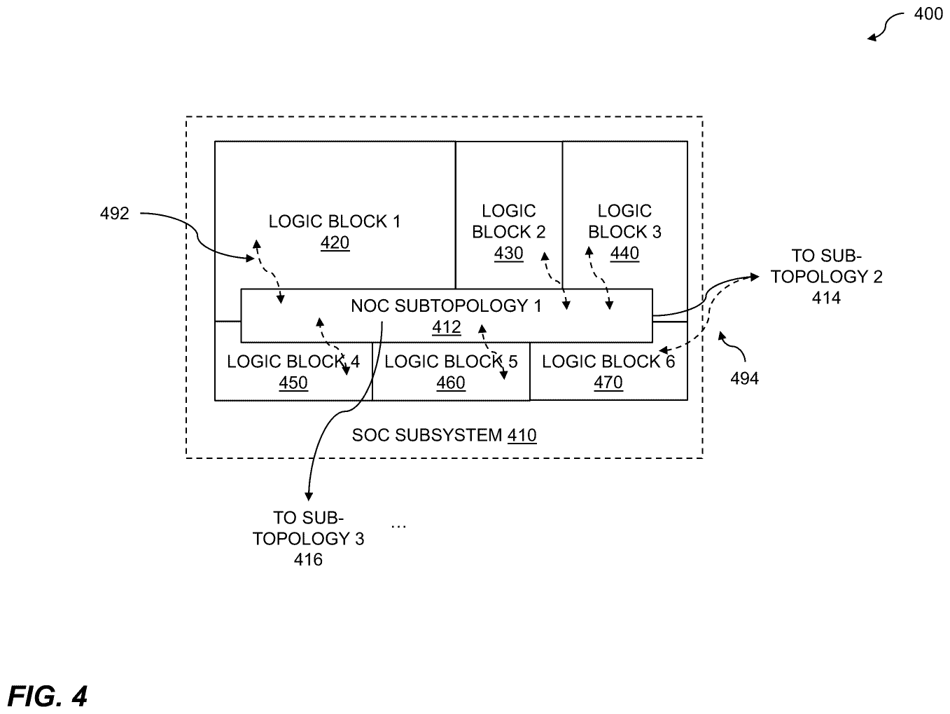

FIG. 4 is an example of a NoC subtopology within a SoC subsystem. As described above and throughout, a SoC subsystem can comprise one or more logic blocks. The SoC can include a NoC topology which enables communication between logic blocks within various subsystems. The NoC topology can be divided into one or more NoC subtopologies. The NoC subtopologies can provide access points for one or more logic blocks within a subsystem to be able to communicate to other logical blocks throughout the SoC via the NoC.

The example 400 includes a SoC subsystem 410. The SoC subsystem can be one of many subsystems included on a SoC. Example subsystems can include a RISC-V subsystem, a PCI-E subsystem, a security subsystem, and so on. The NoC topology within the SoC can be divided into one or more NoC subtopologies which can be included in the various subsystems. In the example 400, NoC subtopology 1 412 has been included in the SoC subsystem. NoC subtopology 1 can enable communications to other subtopologies such as NoC subtopology 2 414 and NoC subtopology 3 416. These other subtopologies can be in different subsystems, the same subsystem, or outside of any subsystem. The subtopologies can include logic, physical wiring, one or more subtopology nodes, and so on. Subtopology nodes can comprise a network interface, a router, ingress ports, egress ports, physical wiring, etc.

The network interface can packetize and/or depacketize data and translate between different communications protocols utilized by various logic and/or subsystems on the SoC. Embodiments include translating, from a protocol running on the plurality of logic blocks, to the one or more communications protocols. In some embodiments, the one or more communications protocols are coherent. In other embodiments, the one or more communications protocols are non-coherent. The network interface can be included in logic blocks within the SoC subsystems or in the NoC nodes within the subtopologies. The physical location of the NoC subtopologies can be arranged on the SoC to optimize communications between logic blocks within or between subsystems. For instance, in example 400, NoC subtopology 1 is placed close to the horizontal center of the SoC subsystem. It is also placed at the edges of most of the logic blocks to provide NoC access to all logic blocks. NoC subtopology 1 can be moved closer to subtopology 2 (to the right), closer to subtopology 3 (to the bottom), and so on to improve timing of communications between the two subsystems. To accommodate timing, performance, floorplanning, etc. constraints, a subtopology can be placed outside of a subsystem. Optimizing subtopology placement can eliminate timing issues from long packetized signals.

In the example 400, the subsystem includes a plurality of logic blocks including logic block 1 420, logic block 2 430, logic block 3 440, logic block 4 450, logic block 5 460, and logic block 6 470. Embodiments include selecting one or more logic blocks within the plurality of logic blocks to be serviced by each of the one or more subtopologies. Any of the logic blocks within the subsystem can be selected to communicate via any subtopology. As shown, logic blocks 1-5 are coupled 492 to NoC subtopology 1 to communicate with other portions of the SoC. In embodiments, the one or more logic blocks are from different SoC subsystems. For example, logic block 6 communicates with subtopology 2 494, even though it is part of the same SoC subsystem as logic blocks 1-5. Allowing logic blocks from different subsystems to be included in a subtopology can optimize timing and performance of signals between logic blocks within and between SoC subsystems. In embodiments, the selecting is based on timing within the one or more logic blocks. For example, logic block 6 can have a critical timing path or a performance critical path to a logic block in subtopology 2. Allowing the logic block to be coupled to another subtopology can reduce delays from logic block to logic block. In embodiments, the selecting can be based on machine learning. Allowing a machine learning algorithm, such as a neural network, to select logic blocks to be included in various subtopologies can optimize the timing of all the paths associated with logical blocks 1-6 concurrently.

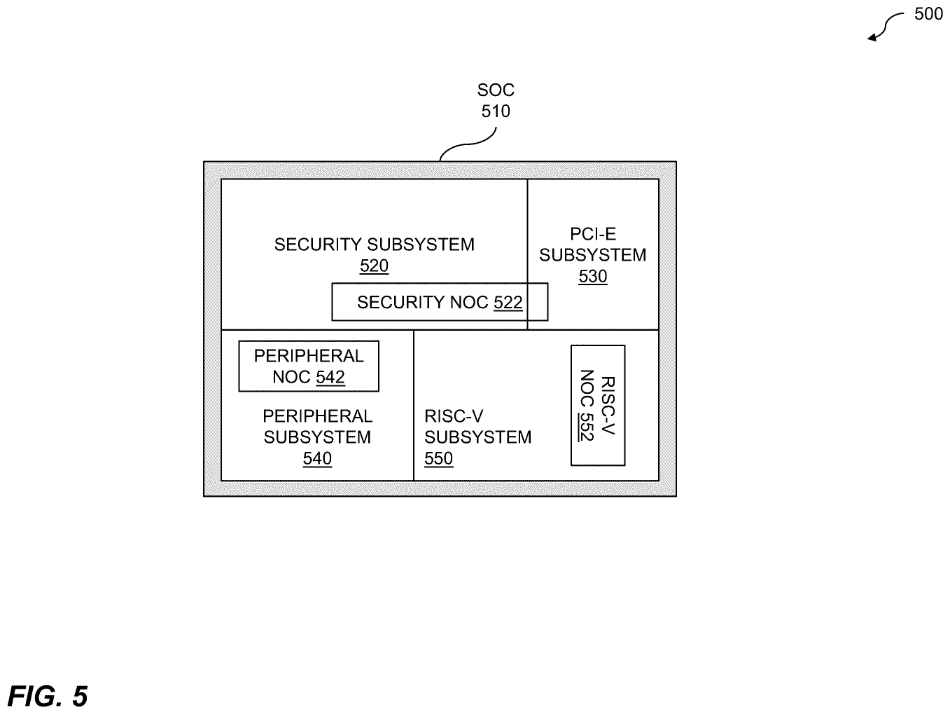

FIG. 5 is a sample floor plan for subtopologies within an SoC. In the sample floor plan 500, an SoC 510 can include a plurality logic blocks. The logic blocks on the SoC can include combinational logic, circuit arrays, etc. and can comprise a functional subsystem such as an application specific integrated circuit (ASIC), one or more processors, memory, input/out devices, external interfaces, graphics processor units (GPUs), modems, and the like. In the sample floor plan 500, the subsystems include a security subsystem 520. The security subsystem can include logic and circuits that provide security functions to an application running on the SoC, such as helping to prevent cybersecurity attacks. The security functions can include encryption/decryption, authenticity verification, verification of security sensors, storage of cryptographic tools, and the like. The sample floor plan 500 includes a PCI-Express (PCI-E) subsystem 530. The PCI-E subsystem can include logic and circuits that provide PCI-E communications to input/output (IO) devices. The sample floor plan 500 includes a peripheral subsystem 540. The peripheral subsystem can include logic and circuits that provide an interface to off-chip peripheral devices including input, output, storage devices, and so on. The sample floor plan 500 includes a RISC-V subsystem 550. The RISC-V subsystem can include logic and circuits that provide one or more processing cores, local caches, memory systems, etc. within the SoC. All of the subsystems can be synthesized, custom designed, verified, timed, and/or floorplanned with the logic blocks as shown in sample floor plan 500. A network-on-a chip (NoC) topology can be created for the SoC. The NoC subtopologies within the SoC can be based on a physical location of the plurality of logic blocks. In embodiments, the one or more subtopologies form an n-dimensional mesh topology. In other embodiments, the one or more subtopologies form a torus topology.

As shown in sample floor plan 500, a security subtopology 522 is integrated into the floor plan of the SoC. The security subtopology can service logic signals within the security subsystem and between the security subsystem and other subsystems in the SoC. A peripheral subtopology 542 is integrated into the floor plan of the SoC. The peripheral subtopology can service logic signals within the peripheral subsystem and between the peripheral subsystem and other subsystems in the SoC. A RISC-V subtopology 552 is integrated into the floor plan of the SoC. The RISC-V subtopology can service logic signals within the RISC-V subsystem and between the RISC-V subsystem and other subsystems in the SoC. The location of any of the subtopologies can be optimized. In embodiments, the optimizing includes selecting one or more logic blocks within the plurality of logic blocks to be serviced by each of the one or more subtopologies. For example, as shown, the security NoC subtopology can include logic blocks from another subtopology, such as the PCI-E subsystem. Thus, in embodiments, the one or more logic blocks are from different SoC subsystems. In some embodiments, the optimizing is based on bandwidth. For example, the location of the subtopologies can be arranged such that high bandwidth signals are located close to the topology (or close to a node in the subtopology). This can eliminate a need to include a pipeline stage which would reduce performance. A subsystem can be small enough that it does not require its own NoC subtopology. A small subsystem can be coupled to one or more NoC nodes within another subtopology to provide packetized communications to other subsystems on the SoC.

In other embodiments, the optimizing is based on latency. Critical timing paths can exist within logic blocks, between logic blocks, between logic blocks and a NoC subtopology, and so on. The SoC can have many such paths that can limit overall frequency and/or performance. The NoC subtopologies can be located to minimize the number of critical timing paths. In addition, nodes within the subtopology can be located to minimize timing delays in logic blocks that have timing challenges. Additional nodes can be added within the subtopology, as space permits, to help solve timing issues as well. The overall optimization can be a challenging task since moving a subtopology (or a node within a subtopology) can case timing on some paths while making it harder to close timing on others. In embodiments, the optimizing is based on machine learning. The machine learning can be based on any type of machine learning model such as a neural network, CNN, KNN, linear regression, and so on. The machine learning model can be trained and used to optimize the location for the NoC subtopologies on the SoC to eliminate as many long signal delays as possible. The machine learning model can optimize the location of one or more nodes within a subtopology. The model can take into account one or more timing estimates of one or more paths between logic blocks. The paths can cross one or more NoC subtopologies. Embodiments include placing the one or more sub-topologies within the SoC, wherein the placing is based on the optimizing. Once optimized, the subtopologies can be placed by physically instantiating them within a subsystem or between subsystems. Routing can then be finalized within the logic block and the subtopology at the same time, allowing for optimization of latency and bandwidth. Embodiments include wiring, using one or more processors, the SoC, wherein the wiring includes the one or more subtopologies. The wiring can enable the sending of information between NoC subtopologies within the SoC.

As mentioned above and throughout, a SoC can include one or more NoC subtopologies. Embodiments include sending data from a sending subtopology within the one or more subtopologies to a receiving subtopology within the one or more subtopologies. The subtopologies can be coupled with a communications protocol. For example, a first logic block with the security subsystem can send a signal to a second logic block within the RISC-V subsystem. The sending can be based on one or more subtopology nodes. The one or more nodes can translate the signal to one or more communications protocols used by the subtopology to communicate with other subtopologies. In embodiments, the one or more communications protocols are coherent. In other embodiments, the one or more communications protocols are noncoherent. The communications protocol can include packets. Information can be sent in the form of packets from a sending node to a receiving node within the same subtopology, or between different subtopologies. The translating can include packetizing the signal. A node that services the second logic block can depacketize the signal and forward the signal to the second logic block. Alternatively, the second logic block can depacketize the signal. In the above example, the security NoC subtopology (the sending subtopology) and the RISC-V subtopology (the receiving subtopology) can be based on synchronous clocks. As such, the sending of packets can be based on a synchronous FIFO. In embodiments, a first clock within the sending subtopology and a second clock within the receiving subtopology are asynchronous. In this case, a clock synchronizer can be implemented to capture data between clock domains. As described above, a clock synchronizer can ensure that data is not lost when transmitting between two different clock domains. The clock synchronizer can comprise a two-flip-flop synchronizer, a toggle synchronizer, a pulse synchronizer, and so on. In embodiments, the clock synchronizer is based on an asynchronous FIFO. The asynchronous FIFO can use the first clock from the sending topology as a write clock while the clock from the receiving subtopology can be used for the read clock. In further embodiments, the sending includes credit-based backpressure. Credit-based backpressure can include notifying, by the receiving topology, that buffer space is available (giving credit to the sending subtopology) to receive data from the sending subtopology. The sending topology can then safely send the data. If no buffer space is available in the receiving subtopology, then credit can be removed resulting in pausing, by the sending subtopology, the sending of until the receiving subtopology can free up additional buffer space to receive additional data.

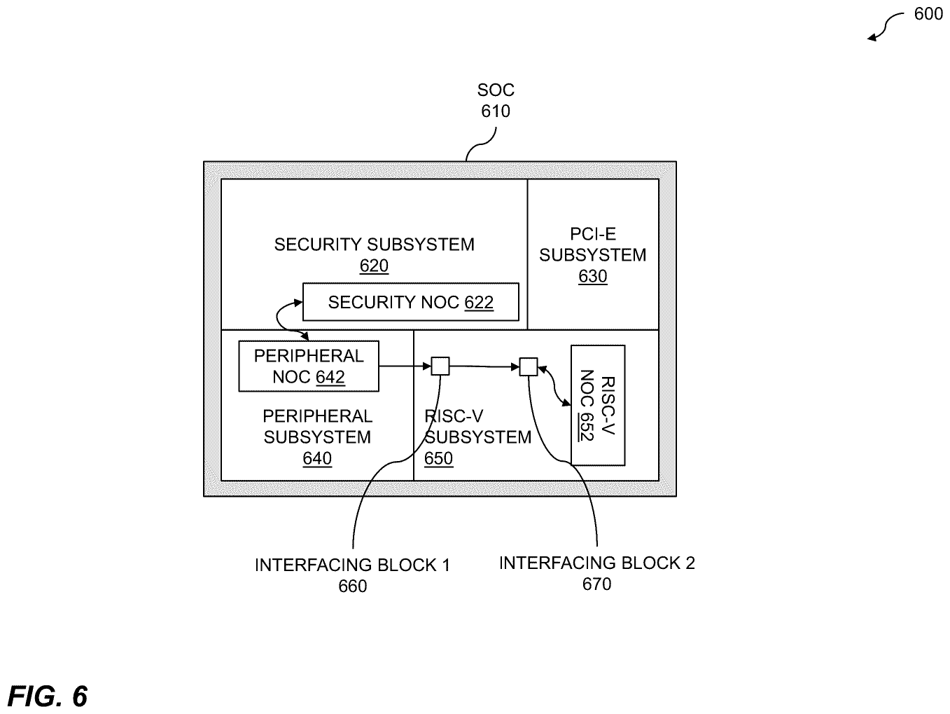

FIG. 6 is a sample floor plan for subtopologies with interfacing blocks. The sample floor plan 600 can include a SoC 610. As described above and throughout, one or more logic blocks on the SoC can include one or more processors, memory, input/out devices, external interfaces, graphics processor units (GPUs), modems, and the like. The SoC includes a security subsystem 620. The security subsystem can include logic and circuits that provide security functions to an application running on the SoC, such as helping to prevent cybersecurity attacks. The security functions can include encryption/decryption, authenticity verification, verification of security sensors, storage of cryptographic tools, and the like. The SoC includes a PCI-E subsystem 630. The PCI-E subsystem can include logic and circuits that provide PCI-E communications to input/output (IO) devices. The SoC includes a peripheral subsystem 640. The peripheral subsystem can include logic and circuits that provide an interface to off-chip peripheral devices including input, output, storage devices, and so on. The SoC includes a RISC-V subsystem 650. The RISC-V subsystem can include logic and circuits that provide one or more processing cores, local caches, memory systems, etc. within the SoC.

The NoC topology can include one or more subtopologies. The one or more subtopologies can be based on a physical location of the one or more logic blocks. The subtopologies can include a structure such as a ring, an n-dimensional mesh, a torus, a k-ary tree, a cube mesh, or any other structure. The location of the subtopologies within a logic block can be optimized with respect to other subtopologies to limit long wire delays. Three NoC subtopologies are shown in sample floor plan 600. Security NoC subtopology 622 is shown within the security subsystem. Peripheral NoC subtopology 642 is shown within the peripheral subsystem. RISC-V NoC subtopology 652 is shown within the RISC-V subsystem. Note that not all logic blocks require their own NoC subtopology. For example, the PCI-E subsystem is shown without a subtopology. This can be due to the size of the PCI-E subsystem and/or number of logic blocks within the PCI-E subsystem. A subsystem can be small enough that it does not require its own NoC subtopology, as in the case with the PCI-E subsystem. Instead, the PCI-E subsystem can be coupled to one or more NoC nodes within another subtopology, for example the RISC-V NoC subtopology, to provide packetized communications to other subsystems.

The subtopologies within the SoC can include one or more nodes. Subtopology nodes can comprise a network interface, a router, ingress ports, egress ports, a physical link such as physical wiring, etc. The network interface can packetize and/or depacketize data, translate between different communications protocols utilized by various logic and/or subsystems on the SoC, and so on. The network interface can be included in logic blocks with the SoC subsystems rather than the NoC nodes. The subtopologies within the SoC can be coupled. The coupling can include a communications protocol. The communications protocol can include packets. Information can be sent in the form of packets from a first node in a sending subtopology to a receiving node within the a receiving subtopology. The sending subtopology and the receiving subtopology can be the same. One or more subtopologies can be coupled. In sample floor plan 600, the security subtopology and the peripheral subtopology are coupled to send data directly to each other. Thus, packetized communications can be enabled between the security subsystem and the peripheral subsystem. However, both the security subtopology and the peripheral subtopology are unable to communicate directly with the RISC V subtopology. The inability to communicate directly can be due to issues such as wire distance, a data width mismatch, a clock frequency mismatch, and so on. A combination of issues between subtopologies is possible, which can prevent some subtopologies from being directly coupled.

The data can be sent from a sending subtopology to a receiving subtopology using one or more interfacing blocks. For example, in sample floor plan 600, a logic block within the peripheral subsystem (which can be the sending subsystem) can send data to a logic block within the RISC-V subsystem (which can be the receiving subsystem). However, as mentioned, those subtopologies are not directly coupled. In embodiments, the coupling comprises inserting a first interfacing block 660 between the sending subtopology and the receiving subtopology. Further embodiments include transmitting the data from the sending subtopology to the first interfacing block. As data is received at the interfacing block, it can be synchronized. As described previously, the sending subtopology clock and the receiving subtopology clock can be asynchronous. Thus, in embodiments, a first clock within the sending subtopology and a second clock within the receiving subtopology are asynchronous. In this case, a clock synchronizer can be used to safely transfer the data. The clock synchronizer can comprise a two-flip-flop synchronizer, a toggle synchronizer, a pulse synchronizer, and so on. Thus, in embodiments, the sending is based on a clock synchronizer. In further embodiments, the clock synchronizer is based on an asynchronous FIFO. In other embodiments, the sending includes credit-based backpressure. The sending subtopology clock and the receiving subtopology clock can be synchronous. In this case, data can be synchronized by a synchronous FIFO. Embodiments include synchronizing the data, wherein the synchronizing is based on the first interfacing block. The first interfacing block can include the synchronizing logic, such as the asynchronous or synchronous FIFO. In some cases, only one interfacing block is needed to bridge between subtopologies. Embodiments include delivering, by the first interfacing block, to the receiving subtopology, the data. Data can be delivered over the protocol in use by the one or more subtopologies. The protocol can include packetized data. Once received by a subtopology node in the receiving subtopology, the data can be depacketized and delivered to the logic block.

In the sample floor plan 600, a second interfacing block 670 can be inserted between the peripheral subsystem and the RISC-V subsystem. In embodiments, the inserting includes adding a second interfacing block between the first interfacing block and the receiving subtopology. Further embodiments include transferring the data from the first interfacing block to the second interfacing block. The transferring can include data synchronization techniques such as those described above. Other embodiments include supplying, by the second interfacing block, to the receiving subtopology, the data. The supplying can include depacketizing the data and delivering it to the receiving logic block. The one or more interfacing blocks can be within a single subtopology. The one or more interfacing blocks comprise one or more pipeline stages to reduce long RC delays in the path between subtopologies. Multiple interfacing blocks (which can comprise pipeline stages) can be added to meet timing requirements. One or more interfacing blocks can be placed in parallel to enable communications from a sending subtopology to more than one receiving subtopology. A clock signal from a sending subtopology can be sent to an interfacing block to synchronize data between subtopologies. Similarly, a clock can be sent between interfacing blocks to synchronize data. The interfacing blocks can include data buffers. For example, if the sending subtopology with a 64-bit data bus sends packetized data to a receiving subtopology with a 32-bit data bus, buffers within an interfacing block must store up to 32 bits of data per clock cycle in order to prevent data loss. Thus, the interface blocks can transfer data between subtopologies with different width data buses.

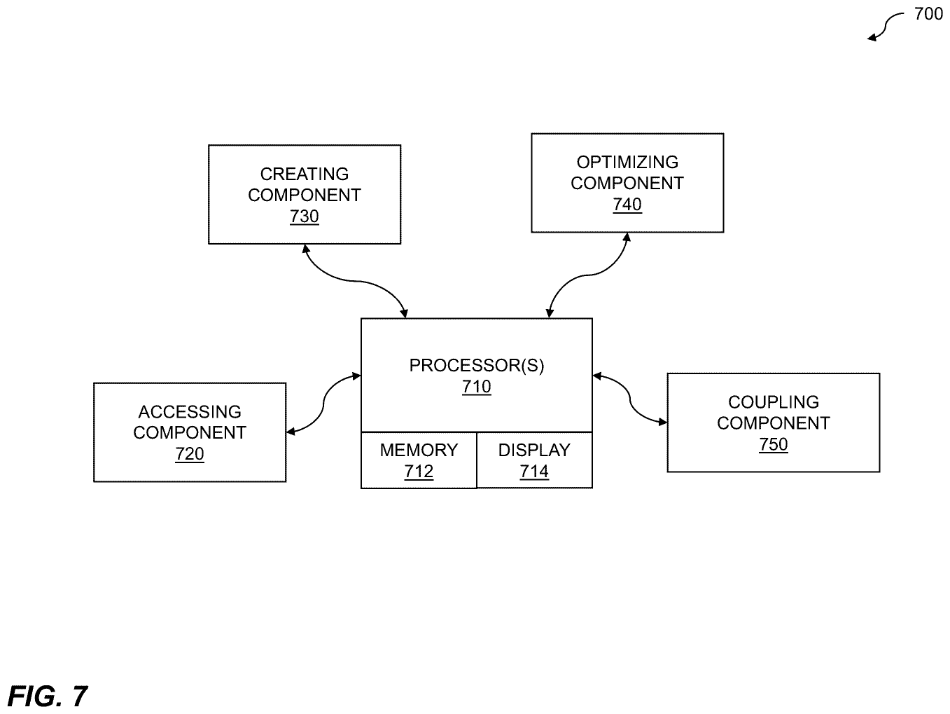

FIG. 7 is a system diagram for a location-based NoC interface with subtopologies. The system 700 can include one or more processors 710 attached to a memory 712 which stores instructions. The system 700 can include a display 714 coupled to the one or more processors 710 for displaying data, video streams, videos, intermediate steps, instructions, and so on. In embodiments, one or more processors 710 are attached to the memory 712 where the one or more processors, when executing the instructions which are stored, are configured to: access a system-on-chip (SoC), wherein the SoC includes one or more logic blocks; create a network-on-a chip (NoC) topology, wherein the NoC topology includes one or more subtopologies, wherein the one or more subtopologies are based on a physical location of the one or more logic blocks, and wherein each subtopology in the one or more subtopologies includes at least one router; optimize a location of the one or more subtopologies; and couple the one or more subtopologies that were placed, wherein the coupling is based on one or more communications protocols.

The system 700 includes an accessing component 720. The accessing component can include functions and instructions for accessing a system-on-chip (SoC), wherein the SoC includes one or more logic blocks. In embodiments, the logic blocks on the SoC can comprise a subsystem. One or more subsystems can include processors, multicore processors, memory, input/out devices, external interfaces, graphics processor units (GPUs), security logic, modems, and the like. The SoC can be a multi-core SoC (MCSoC). The logic blocks on the SoC can communicate via different protocols. These protocols can be a mix of coherent and non-coherent protocols.

The system 700 includes a creating component 730. The creating component 730 can include functions and instructions for creating a network-on-chip (NoC) topology, wherein the NoC topology includes one or more subtopologies, wherein the one or more subtopologies are based on a physical location of the plurality of logic blocks, and wherein each subtopology in the one or more subtopologies includes at least one router. The NoC topology can enable communications between and among logic blocks, subsystems, etc. within the SoC. The NoC topology can include a communications structure such as a ring, an n-dimensional mesh, a torus, a k-ary tree, a cube mesh, or any other structure. The NoC topology can comprise one or more subtopologies. The subtopologies can include logic, physical wiring, one or more subtopology nodes, and so on. Subtopology nodes can comprise a network interface, a router, ingress ports, egress ports, one or more physical links, etc. The network interface can packetize and/or depacketize data and translate between different communications protocols utilized by various logic and/or subsystems on the SoC. The network interface can be included in logic blocks within the SoC subsystems rather than the NoC nodes. Each subtopology includes at least one router. The routers can include ingress and egress ports. The routers can direct packetized network traffic to other subtopologies within and outside of the subsystem. The ingress and egress ports can couple a logic block within the subtopology to another logic block in the subtopology, another node in the subtopology, a node in a different subtopology, and so on. Packetized network traffic sent between nodes can include data, a logic block ID, coherency data, priority information, or other data. The one or more subtopologies are based on a physical location of the plurality of logic blocks. The subtopology can be customized to enable communication between the logic blocks in the most efficient manner. The customizing can include adding or subtracting nodes to an existing subtopology, moving the subtopology, changing the shape of the subtopology, and so on. The subtopologies can take on any shape or location to accommodate optimized communications for the logic blocks. The logic blocks can be concurrently synthesized, simulated, timed, etc. with the NoC subtopology which services them.

The system 700 includes an optimizing component 740. The optimizing component can include functions and instructions for optimizing a location of the one or more subtopologies. The physical location of each NoC subtopology can be arranged on the SoC to optimize communications between logic blocks within or between subsystems. To accommodate timing, performance, floorplanning, and other constraints, a subtopology can be placed outside of a subsystem. Optimizing subtopology placement can eliminate timing issues from long packetized signals. The optimizing can be based on a human designer, a place-and-route algorithm, machine learning, machine learning NoC (MLNoC) technology, and so on. The results of the optimizing can be modified by a human designer to further optimize for a variety of design factors such as timing, bandwidth, and so on. The optimization can include synthesizing the subtopology with different parameters such as timing constraints, logic minimization, and so on. The synthesizing can include concurrently synthesizing the subtopology and one or more logic blocks to maximize performance, minimize logic, improve timing, and so on. The overall size, shape, and/or location of the subtopology can be optimized to accommodate factors of size, chip location, buffer sizes, quality of service (QOS) policies, arbitration, latency, bandwidth requirements, etc. of the logic block. The optimizing can be based on latency, bandwidth, machine learning (which can be based on a machine learning model such as a neural network (NN), convolutional neural network (CNN), K-nearest neighbor algorithm (KNN), etc.), and so on. The optimizing can include selecting one or more logic blocks within the plurality of logic blocks to be serviced by each of the one or more subtopologies. The one or more logic blocks can be from different SoC subsystems. Logic blocks can be assigned to any subtopology with the NoC to enable and optimize necessary packetized communication within and between SoC subsystems. The selecting can be based on timing within the one or more logic blocks. For example, if the timing of signals within the logic block is critical or tight, a closer NoC subtopology can be chosen. The selecting can also be based on machine learning.

The system 700 includes a coupling component 750. The coupling component can include functions and instructions for coupling the one or more subtopologies that were placed, wherein the coupling is based on one or more communications protocols. The coupling can include one or more subtopology nodes. Since subtopologies within the NoC can vary in data width, clocks, and so on, the coupling can ensure that data can be sent/received between subtopologies. For example, the coupling can include buffers to ensure that data is not lost when a subtopology with a larger data width (e.g., 512-bits) sends data to a subtopology with a smaller data with (e.g., 128-bits). A sending subtopology and a receiving subtopology can implement different clock domains. In this case, the coupling can include a data synchronizer to cross clock domains without losing data. In embodiments, the coupling is based on one or more communications protocols. The communications protocols can include packets. Information can be sent in the form of packets from a sending node to a receiving node within the subtopology. The communications protocol can include unidirectional, bidirectional, etc. communications between the sending node and receiver nodes. The communications protocol can include handshaking between the one or more subtopologies. In embodiments, the one or more communications protocols are coherent, such as AMBA CHI. A coherent system can ensure that caches within subsystems of the SoC share data and that no cache obtains data that is out of date. In other embodiments, the one or more communications protocols are non-coherent, such as AMBA AXI. In a non-coherent protocol, each subsystem must manage caches independently from other subsystems.

The system 700 can include a computer program product embodied in a non-transitory computer readable medium for chip floor planning, the computer program product comprising code which causes one or more processors to perform operations of: accessing a system-on-chip (SoC), wherein the SoC includes a plurality of logic blocks; creating a network-on-chip (NoC) topology, wherein the NoC topology includes one or more subtopologies, wherein the one or more subtopologies are based on a physical location of the plurality of logic blocks, and wherein each subtopology in the one or more subtopologies includes at least one router; optimizing a location of the one or more subtopologies; and coupling the one or more subtopologies that were placed, wherein the coupling is based on one or more communications protocols.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions-generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A computer-implemented method for chip floor planning comprising:
accessing a system-on-chip (SoC), wherein the SoC includes a plurality of logic blocks;
creating a network-on-chip (NoC) topology, wherein the NoC topology includes one or more subtopologies, wherein the one or more subtopologies are based on a physical location of the plurality of logic blocks, and wherein each subtopology in the one or more subtopologies includes at least one router;
optimizing a location of the one or more subtopologies; and
coupling the one or more subtopologies that were placed, wherein the coupling is based on one or more communications protocols.

2. The method of claim 1 further comprising sending data from a sending subtopology within the one or more subtopologies to a receiving subtopology within the one or more subtopologies.

3. The method of claim 2 wherein a first clock within the sending subtopology and a second clock within the receiving subtopology are asynchronous.

4. The method of claim 3 wherein the sending is based on a clock synchronizer.

5. The method of claim 4 wherein the clock synchronizer is based on a synchronous FIFO, and wherein the sending includes credit-based backpressure.

6. The method of claim 2 wherein the coupling comprises inserting a first interfacing block between the sending subtopology and the receiving subtopology.

7. The method of claim 6 further comprising transmitting the data from the sending subtopology to the first interfacing block.

8. The method of claim 7 further comprising synchronizing the data, wherein the synchronizing is based on the first interfacing block.

9. The method of claim 8 further comprising delivering, by the first interfacing block, to the receiving subtopology, the data.

10. The method of claim 7 wherein the inserting includes adding a second interfacing block between the first interfacing block and the receiving subtopology.

11. The method of claim 10 further comprising transferring the data from the first interfacing block to the second interfacing block.

12. The method of claim 11 further comprising supplying, by the second interfacing block, to the receiving subtopology, the data.

13. The method of claim 1 further comprising translating, from a protocol running on the plurality of logic blocks, to the one or more communications protocols.

14. The method of claim 13 wherein the one or more communications protocols are coherent.

15. The method of claim 13 wherein the one or more communications protocols are non-coherent.

16. The method of claim 1 wherein the optimizing includes selecting one or more logic blocks within the plurality of logic blocks to be included in each of the one or more subtopologies.

17. The method of claim 16 wherein the one or more logic blocks are from different SoC subsystems.

18. The method of claim 17 wherein the selecting is based on timing within the one or more logic blocks.

19. The method of claim 16 wherein the selecting is based on machine learning.

20. The method of claim 1 wherein the optimizing is based on machine learning.

21. The method of claim 1 wherein the optimizing is based on bandwidth.

22. The method of claim 1 wherein the optimizing is based on latency.

23. The method of claim 1 wherein the one or more subtopologies form an n-dimensional mesh topology.

24. The method of claim 1 wherein the one or more subtopologies form a torus topology.

25. The method of claim 1 wherein the coupling includes placing the one or more subtopologies within the SoC, wherein the placing is based on the optimizing.

26. The method of claim 1 further comprising wiring, using one or more processors, the SoC, wherein the wiring includes the one or more subtopologies.

27. A computer program product embodied in a non-transitory computer readable medium for chip floor planning, the computer program product comprising code which causes one or more processors to perform operations of:
accessing a system-on-chip (SoC), wherein the SoC includes one or more logic blocks;
creating a network-on-a chip (NoC) topology, wherein the NoC topology includes one or more subtopologies, wherein the one or more subtopologies are based on a physical location of the one or more logic blocks, and wherein each subtopology in the one or more subtopologies includes at least one router;
optimizing a location of the one or more subtopologies; and
coupling the one or more subtopologies that were placed, wherein the coupling is based on one or more communications protocols.

28. A computer system for chip floor planning, comprising:
a memory which stores instructions;
one or more processors attached to the memory wherein the one or more processors, when executing the instructions which are stored, are configured to:
access a system-on-chip (SoC), wherein the SoC includes one or more logic blocks;
create a network-on-a chip (NoC) topology, wherein the NoC topology includes one or more subtopologies, wherein the one or more subtopologies are based on a physical location of the one or more logic blocks, and wherein each subtopology in the one or more subtopologies includes at least one router;
optimize a location of the one or more subtopologies; and
couple the one or more subtopologies that were placed, wherein the coupling is based on one or more communications protocols.
